(19) United States
(12) Patent Application Publication
(10) Pub. No.: US 2025/0194092 A1
(43) Pub. Date: Jun. 12, 2025

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Liang Yi, Singapore (SG); Chi Ren, Singapore (SG)

(73) Assignee: UNITED MICROELECTRONICS CORP., Hsin-Chu City (TW)

(21) Appl. No.: 18/420,694

(22) Filed: Jan. 23, 2024

(30) Foreign Application Priority Data
Dec. 11, 2023 (TW) 112148110

(51) Int. Cl. H10B 43/35

(52) U.S. Cl. CPC H10B 43/35

(57) ABSTRACT

A semiconductor device includes a first memory gate, a second memory gate, a select gate and an inner spacer. The first memory gate is disposed on a substrate. The second memory gate is disposed on the substrate. The select gate is disposed on the substrate and between the first memory gate and the second memory gate. The inner spacer is disposed on a side surface of the select gate, in which each of the first memory gate and the second memory gate includes a capping layer disposed at a top end thereof, each of the capping layers has a curved side surface facing the select gate, and a top end of the inner spacer is adjacent to a bottom end of each of the capping layers.

### BACKGROUND OF THE INVENTION

### 1. Field of the Invention

The present disclosure relates to the field of semiconductor devices, and more particularly, to a semiconductor device applicable to a memory cell and a method for fabricating the same.

### 2. Description of the Prior Art

With the vigorous development of cutting-edge technologies, such as Internet of Things, edge computing and artificial intelligence, capabilities for processing huge information are required, and memory cells play an indispensable role. When the information needed to be processed is huge, the required memory cells are increased accordingly. Even electronic products only with basic functions also include millions of memory cells. Therefore, how to improve the properties of memory cells, such as simplifying the manufacturing process and reducing the volume, to reduce costs and meet the today's requirement for miniaturized electronic products, is a goal of relevant industries.

### SUMMARY OF THE INVENTION

According to one aspect of the present disclosure, a semiconductor device includes a first memory gate, a second memory gate, a select gate and an inner spacer. The first memory gate is disposed on a substrate. The second memory gate is disposed on the substrate. The select gate is disposed on the substrate and between the first memory gate and the second memory gate. The inner spacer is disposed on a side surface of the select gate. Each of the first memory gate and the second memory gate includes a capping layer disposed at a top end thereof, each of the capping layers has a curved side surface facing the select gate, and a top end of the inner spacer is adjacent to a bottom end of each of the capping layers.

According to another aspect of the present disclosure, a method for fabricating a semiconductor device includes steps as follows. A first gate material stack and a hard mask are sequentially formed on a substrate. A portion of the hard mask is removed to form a first recess. A first spacer is formed on a side surface of the hard mask facing the first recess. A portion of the first gate material stack not covered by the first spacer and the hard mask is removed to form a second recess. An inner spacer is formed on a side surface of the first gate material stack facing the second recess. A second gate material stack is formed in the first recess and the second recess. A remaining portion of the hard mask is removed. Another portion of the first gate material stack not covered by the first spacer, a portion of the second gate material stack and a portion of the first spacer are removed to form a first memory gate, a second memory gate and a select gate on the substrate, in which a remaining portion of the first spacer forms a capping layer of the first memory gate and a capping layer of the second memory gate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3, FIG. 4, FIG. 5, FIG. 6, FIG. 7, FIG. 8, FIG. 9 and FIG. 10 are schematic cross-sectional views showing steps of a method for fabricating a semiconductor device according to an embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

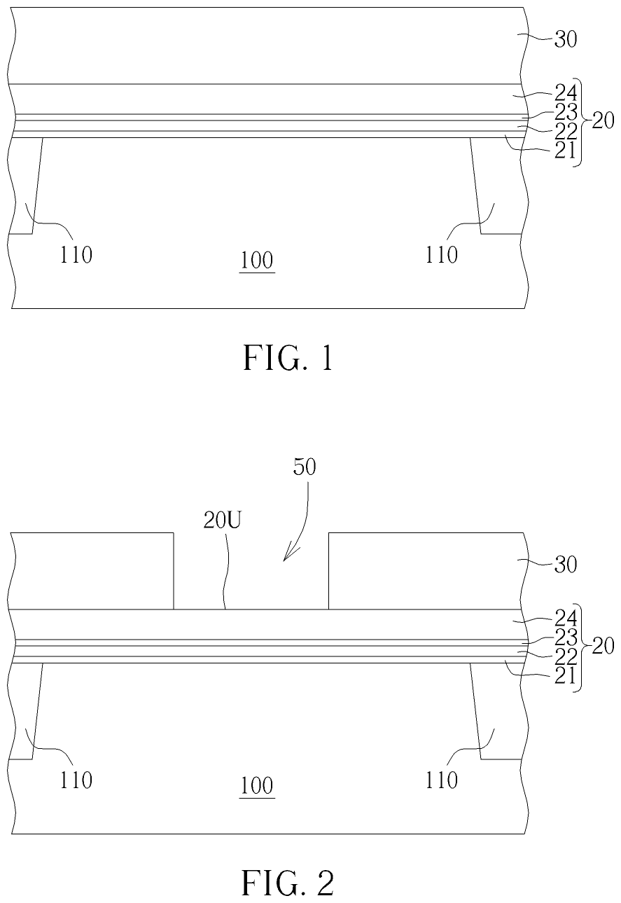

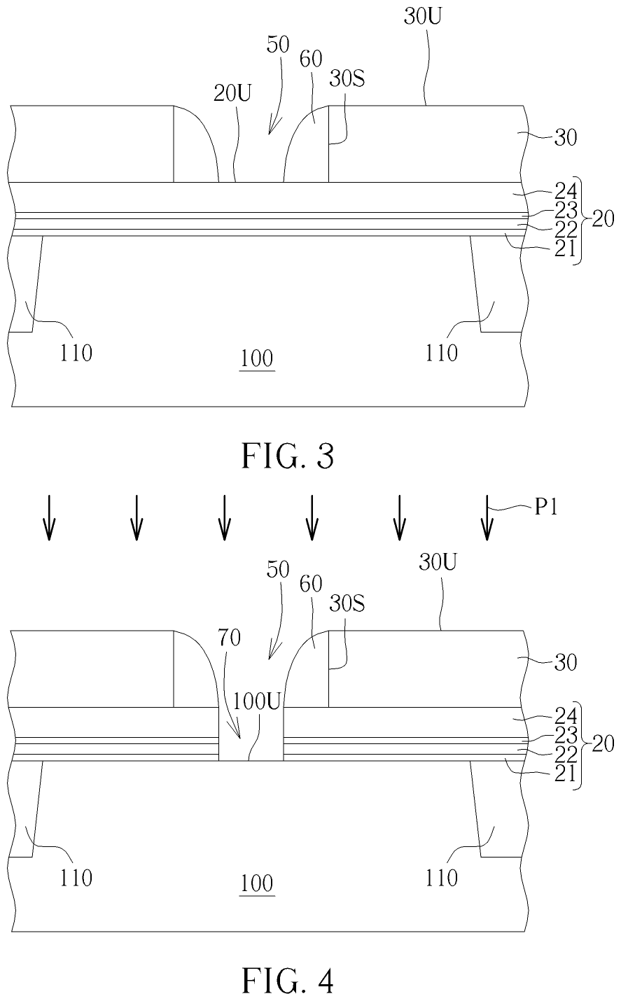

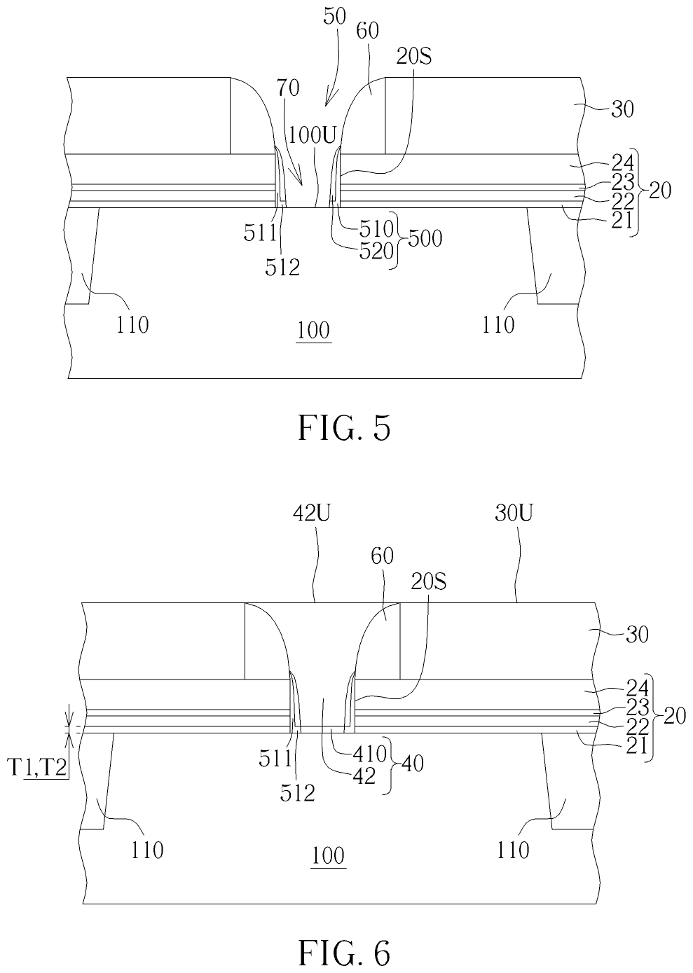

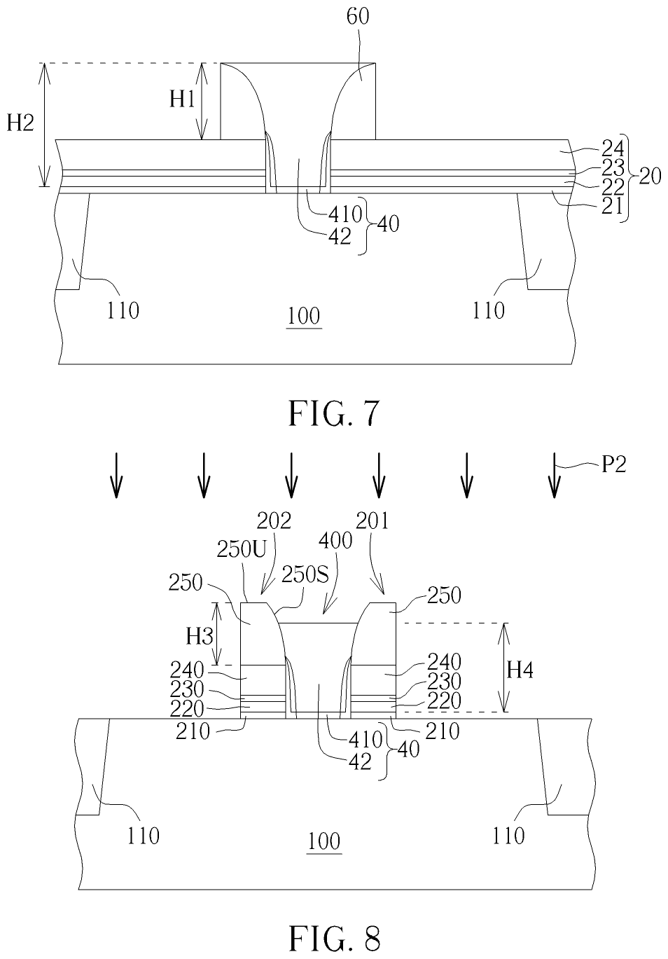

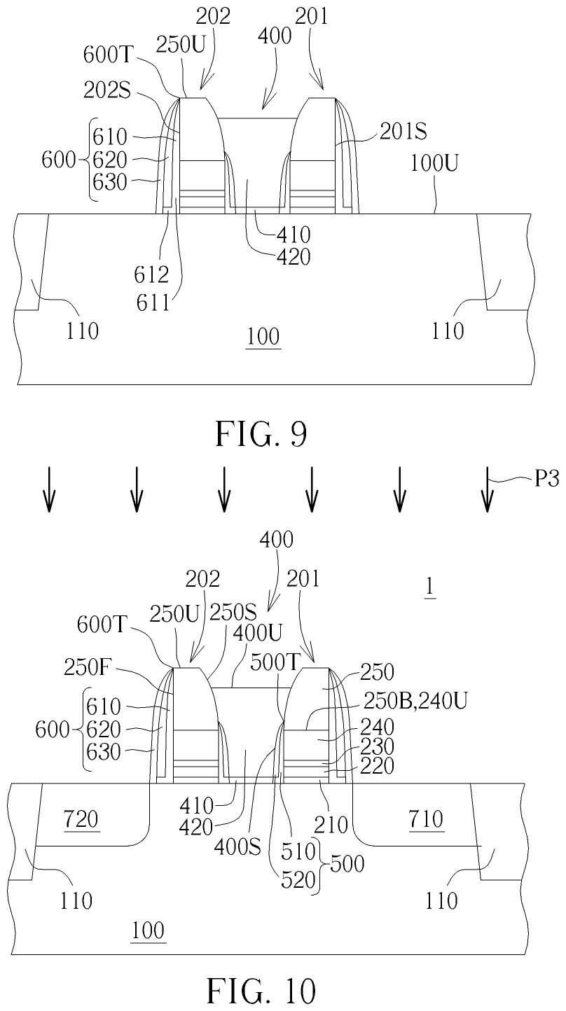

Please refer to FIG. 1 to FIG. 10, which are schematic cross-sectional views showing steps of a method for fabricating a semiconductor device according to an embodiment of the present disclosure. In the embodiment, the semiconductor device 1 (see FIG. 10) is exemplarily an NMOS transistor for explanation. In FIG. 1, a substrate 100 is firstly provided. The substrate 100 may be a silicon substrate, an epitaxial silicon substrate, a silicon carbide substrate or a silicon on insulator (SOI) substrate. Next, at least one shallow trench isolation (STI) surrounding each active region is formed in the substrate 100. For example, the two insulating structures 110 in FIG. 1 may be a left portion and a right portion of a shallow trench isolation, and the region between the two insulating structures 110 may be an active region. The material of the insulating structure 110 may include a dielectric material, such as silicon dioxide. Next, an ion implantation process may be performed to form a well region (not shown) in the substrate 100. The dopant of the well region may be adjusted depending on the subsequently formed semiconductor device 1 being applied to an NMOS transistor or a PMOS transistor. In the embodiment, the semiconductor device 1 is exemplarily an NMOS transistor. Therefore, the well region is a P-type well region, and the well region may be doped with P-type dopants, such as boron, indium, etc.

Next, the first gate material stack 20 and the hard mask 30 are sequentially formed on the substrate 100, in which forming the first gate material stack 20 includes sequentially forming a gate insulating material layer 21, a charge storage material layer 22, a blocking insulating material layer 23 and a conductive gate material layer 24 on the substrate 100. The material of the gate insulating material layer 21 may include an oxide or a high dielectric constant material. The oxide may include, for example, silicon dioxide (SiO₂). The high dielectric constant material may include, for example, a dielectric material with a dielectric constant greater than 10. The material of the charge storage material layer 22 may include a conductor for storing charges, such as doped polycrystalline silicon, or may include a non-conductor for capturing charges, such as silicon nitride (SiN), to form a charge trapping layer to store charges. The material of the blocking insulating material layer 23 may include an oxide or a high dielectric constant material. The oxide may include silicon dioxide. The high dielectric constant material, for example, may include a dielectric material with a dielectric constant greater than 10. The material of the conductive gate material layer 24 may include conductive materials, such as doped polycrystalline silicon, doped amorphous silicon, metal or metal compounds. The material of the hard mask 30 may include silicon dioxide (SiO₂), silicon nitride (SiN), silicon carbide (SiC) and/or silicon oxynitride (SiON), but not limited thereto. According to an embodiment of the present disclosure, the material of the hard mask 30 includes silicon nitride.

Next, as shown in FIG. 2, a portion of the hard mask 30 may be removed through semiconductor processes, such as lithography process and etch process, to form a first recess 50, so that a portion of the top surface 20U of the first gate material stack 20 is exposed.

Next, as shown in FIG. 3, a first spacer 60 is formed on a side surface 30S of the hard mask 30 facing the first recess 50. For example, a first spacer material layer (not shown) may be formed through a deposition process to fully cover the top surface 30U and the side surface 30S of the hard mask 30 and the top surface 20U of the first gate material stack 20 exposed from the first recess 50, and then a portion of the first spacer material layer is removed by an etch back process to form the first spacer 60. The first spacer 60 may be a single material layer or a stack of material layers. The material of the first spacer 60 may include an oxide and/or a nitride, such as silicon dioxide, silicon nitride, silicon oxynitride or silicon carbonitride. According to an embodiment of the present disclosure, the material of the first spacer 60 includes silicon dioxide.

Next, as shown in FIG. 4, a self-aligned etch process P1 may be performed with the first spacer 60 and the hard mask 30 as the etching mask, in which a single etch or multiple etches may be performed downwardly along the first spacer 60 to remove the portion of the first gate material stack 20 not covered by the first spacer 60 and the hard mask 30 to form the second recess 70, so that a portion of the top surface 100U of the substrate 100 is exposed, in which the second recess 70 is communicated with the first recess 50. With the first spacer 60 and the hard mask 30 being the etching mask to perform the self-aligned etch process P1, there is no need to fabricate an extra etching mask, which is beneficial to simplify the process.

Next, as shown in FIG. 5, an inner spacer 500 is formed on the side surface 20S of the first gate material stack 20 facing the second recess 70. Herein, the inner spacer 500 exemplarily includes a first inner spacer layer 510 and a second inner spacer layer 520 from inside to outside. For example, a first inner spacer material layer (not shown) and a second inner spacer material layer (not shown) may be sequentially formed through a deposition process to fully cover the hard mask 30, the first spacer 60 and the top surface 100U of the substrate 100 exposed from the second recess 70, and then a portion of the first inner spacer material layer and a portion of the second inner spacer material layer are removed by an etch process to form the first inner spacer layer 510 and the second inner spacer layer 520, in which the first inner spacer layer 510 has a L-shaped cross section, and the second inner spacer layer 520 has an I-shaped cross section. That is, the first inner spacer layer 510 may include a vertical portion 511 and a horizontal extension portion 512. The extension direction of the vertical portion 511 is perpendicular to the extension direction of the horizontal extension portion 512, and the second inner spacer layer 520 has no horizontal extension portion. In other embodiments, the first inner spacer layer 510 and the second inner spacer layer 520 both having I-shaped cross sections may be sequentially formed through continuous processes of deposition, etch, deposition and etch. The materials of the first inner spacer layer 510 and the second inner spacer layer 520 may independently include an oxide and/or a nitride, such as silicon dioxide, silicon nitride, silicon oxynitride or silicon carbonitride. According to an embodiment of the present disclosure, the material of the first inner spacer layer 510 includes silicon dioxide, and the material of the second inner spacer layer 520 includes silicon nitride.

Next, as shown in FIG. 6, the second gate material stack 40 is formed in the first recess 50 and the second recess 70, in which forming the second gate material stack 40 may include sequentially forming the gate insulating layer 410 and the conductive gate material layer 42 on the substrate 100. The material of the gate insulating layer 410 may include an oxide, and the material of the conductive gate material layer 42 may include a conductive material, such as doped polycrystalline silicon, doped amorphous silicon, metal or metal compounds. For example, the gate insulating layer 410 may be formed through a thermal oxidation process. In this case, as shown in FIG. 6, the gate insulating layer 410 has a rectangular cross section. The thermal oxidation process may include in-situ steam generation (ISSG) oxidation process, wet furnace oxidation process, or dry furnace oxidation process, but not limited thereto. Afterward, the conductive gate material layer 42 is formed through a deposition process, and then a planarization process such as a chemical mechanical polishing (CMP) process and/or an etch back process is performed to remove a portion of the conductive gate material layer 42, so that the top surface 42U of the conductive gate material layer 42 is aligned with the top surface 30U of the hard mask 30. In other embodiments, the gate insulating layer 410 may be formed through a deposition process. In this case, a gate insulating layer with a U-shaped cross section (not shown) may be obtained in the first recess 50 and the second recess 70. In FIG. 6, the thickness T2 of the gate insulating layer 410 is identical to the thickness T1 of the gate insulating material layer 21. However, it is only exemplary, and the present disclosure is not limited thereto.

Next, as shown in FIG. 7, the remaining portion of the hard mask 30 may be removed through semiconductor processes, such as an etch process and a cleaning process, so that the portion of the first gate material stack 20 not covered by the first spacer 60 and the second gate material stack 40 may be exposed.

Next, as shown in FIG. 8, a self-aligned etch process P2 may be performed with the first spacer 60 as the etching mask, in which a single etch or multiple etches may be performed downwardly along the first spacer 60 to remove a portion of the first gate material stack 20 not covered by the first spacer 60. During the self-aligned etch process P2, a portion of the second gate material stack 40 (herein, a portion of the conductive gate material layer 42) and a portion of the first spacer 60 are also removed, so as to form the first memory gate 201, the second memory gate 202 and the select gate 400 on the substrate 100. The remaining portion of the first spacer 60 forms the capping layer 250 of the first memory gate 201 and the capping layer 250 of the second memory gate 202. Each of the capping layers 250 has a curved side surface 250S facing the select gate 400. The remaining portions of the conductive gate material layer 24, the blocking insulating material layer 23, the charge storage material layer 22 and the gate insulating material layer 21 form the conductive gate layers 240, the blocking insulating layers 230, the charge storage layers 220 and the gate insulating layers 210 of the first memory gate 201 and the second memory gate 202. The remaining portion of the conductive gate material layer 42 forms the conductive gate layer 420 of the select gate 400.

Compared with the first spacer 60 in FIG. 7, the height H3 of the capping layer 250 is less than the height H1 of the first spacer 60 and has a flat top surface 250U. Compared with the conductive gate material layer 42 in FIG. 7, the height H4 of the conductive gate layer 420 is less than the height H2 of the conductive gate material layer 42 and does not completely cover the curved side surface 250S of the capping layer 250.

Next, as shown in FIG. 9, an outer spacer 600 is formed on the outer side surface 201S of the first memory gate 201 and the outer side surface 202S of the second memory gate 202, in which the top end 600T of the outer spacer 600 is aligned with the top surface 250U of each of the capping layers 250. In addition, the outer spacer 600 exemplarily includes a first outer spacer layer 610, a second outer spacer layer 620 and a third outer spacer layer 630 from the inside to outside. For example, a first outer spacer material layer (not shown) and a second outer spacer material layer (not shown) may be sequentially formed through a deposition process to fully cover the first memory gate 201, the second memory gate 202, the select gate 400 and the exposed top surface 100U of the substrate 100, and then a portion of the first outer spacer material layer and the second outer spacer material layer are removed by an etch process to form the first outer spacer layer 610 and the second outer spacer layer 620. Next, the third outer spacer layer 630 is formed by semiconductor processes, such as a deposition process and an etch process. The first outer spacer layer 610 has an L-shaped cross section, the second outer spacer layer 620 has an I-shaped cross section, and the third outer spacer layer 630 has an I-shaped cross section. That is, the first outer spacer layer 610 may include a vertical portion 611 and a horizontal extension portion 612. The extension direction of the vertical portion 611 is perpendicular to the extension direction of the horizontal extension portion 612, and the second outer spacer layer 620 and the third outer spacer layer 630 do not have horizontal extension portions. The materials of the first outer spacer layer 610, the second outer spacer layer 620 and the third outer spacer layer 630 may independently include an oxide and/or a nitride, such as silicon dioxide, silicon nitride, silicon oxynitride or silicon carbonitride. According to an embodiment of the present disclosure, the material of the first outer spacer layer 610 includes silicon dioxide, the material of the second outer spacer layer 620 includes silicon nitride, and the material of the third outer spacer layer 630 includes silicon dioxide. In other embodiments, the first outer spacer layer 610, the second outer spacer layer 620 and the third outer spacer layer 630 all having I-shaped cross sections may be sequentially formed through continuous processes of deposition, etch, deposition, etch, deposition, and etch.

Next, as shown in FIG. 10, the ion implantation process P3 may be performed to form two doped regions 710 and 720 in the substrate 100, in which the doped region 710 is adjacent to the first memory gate 201, and the other doped region 720 is adjacent to the second memory gate 202. The conductivity types of the two doped regions 710 and 720 are the same with each other and are different from the conductivity type of the well region. In the embodiment, the well region is a P-type well region, and the two doped regions 710 and 720 are N-type doped regions. Therefore, the ion implantation process P3 is to implant N-type dopants into the substrate 100. For example, the N-type dopants may include, but not limited to, arsenic, phosphorus, etc. Thereby, the fabrication of the semiconductor device 1 is completed.

The aforementioned film layers, such as the gate insulating material layer 21, the charge storage material layer 22, the blocking insulating material layer 23, the conductive gate material layer 24, the hard mask 30, the first spacer material layer, the first inner spacer material layer, the second inner spacer material layer, the gate insulating layer 410, the conductive gate material layer 42, the first outer spacer material layer, the second outer spacer material layer and the third outer spacer material layer, may be formed by any suitable methods. For example, the methods may be, but are not limited to, molecular-beam epitaxy (MBE), chemical vapor deposition (CVD), metal organic chemical vapor deposition (MOCVD), hydride vapor phase epitaxy (HVPE) and atomic layer deposition (ALD).

Please refer to FIG. 10, which is a schematic cross-sectional view of a semiconductor device 1 according to an embodiment of the present disclosure. The semiconductor device 1 includes the first memory gate 201, the second memory gate 202, the select gate 400 and the inner spacer 500. The first memory gate 201 is disposed on the substrate 100, the second memory gate 202 is disposed on the substrate 100, and the select gate 400 is disposed on the substrate 100 and between the first memory gate 201 and the second memory gate 202. The inner spacer 500 is disposed on the side surface 400S of the select gate 400. Each of the first memory gate 201 and the second memory gate 202 includes a capping layer 250 disposed at a top end (not labeled) thereof. Each of the capping layers 250 has a curved side surface 250S facing the select gate 400, and the top end 500T of the inner spacer 500 is adjacent to the bottom end 250B of each of the capping layers 250. The aforementioned “the top end 500T of the inner spacer 500 is adjacent to the bottom end 250B of each of the capping layers 250” may refer that the top end 500T of the inner spacer 500 is slightly higher than the bottom end 250B of the capping layer directly contacting thereto, or it may refer that a distance in the vertical direction between the top end 500T of the inner spacer 500 and the bottom end 250B of the capping layer 250 directly contacting thereto is less than a distance in the vertical direction between the top end 500T of the inner spacer 500 and the top surface 250U of the capping layer 250 directly contacting thereto.

Specifically, the first memory gate 201 may include the gate insulating layer 210, the charge storage layer 220, the blocking insulating layer 230, the conductive gate layer 240 and the capping layer 25 sequentially disposed on the substrate 100 from bottom to top. The second memory gate 202 may include the gate insulating layer 210, the charge storage layer 220, the blocking insulating layer 230, the conductive gate layer 240 and the capping layer 250 sequentially disposed on the substrate 100 from bottom to top. Each of the capping layer 250 may have a vertical side surface 250F opposite to the curved side surface 250S. That is, each of the capping layers 250 has an asymmetrical cross-sectional shape.

The materials of the gate insulating layer 210, the charge storage layer 220, the blocking insulating layer 230, the conductive gate layer 240 and the capping layer 250 may be respectively the same as the gate insulating material layer 21, the charge storage material layer 22, the blocking insulating material layer 23, the conductive gate material layer 24 and the first spacer 60, and are not repeated herein. The first memory gate 201 and the second memory gate 202 may be charge-trapping type memory cells. According to an embodiment of the present disclosure, the materials of the gate insulating layer 210, the charge storage layer 220, and the blocking insulating layer 230 may be an oxide, a nitride and an oxide, respectively. That is, the first memory gate 201 and the second memory gate 202 may be ONO-type memory cells. The operating principle of the ONO-type memory cells is well known in the art and is not repeated herein.

The select gate 400 may include the gate insulating layer 410 and the conductive gate layer 420 sequentially disposed on the substrate 100 from bottom to top. The material of the conductive gate layer 420 may be the same as the material of the conductive gate material layer 42 and are not repeated herein. The top surface 400U of the select gate 400 is lower than the top surface 250U of each of the capping layers 250, and is between the top surface 250U of each of the capping layers 250 and the bottom end 250B of each of the capping layers 250. The top surface 400U of the select gate 400 is higher than the top end 500T of the inner spacer 500, and the top end 500T of the inner spacer 500 is higher than the top surface 240U of the conductive gate layer 240. Thereby, it may effectively isolate the influence of the top corners of the conductive gate layer 240 on the select gate 400.

The semiconductor device 1 may further include an outer spacer 600. The outer spacer 600 is disposed on the outer side surface 201S (see FIG. 9) of the first memory gate 201 and the outer side surface 202S (see FIG. 9) of the second memory gate 202. The top end 600T of the outer spacer 600 is aligned with the top surface 250U of the capping layer 250. Each of the inner spacer 500 and the outer spacer 600 may be a multi-layer structure. Herein, the inner spacer 500 is a double-layer structure and includes the first inner spacer layer 510 and the second inner spacer layer 520 from inside to outside. The outer spacer 600 is a three-layer structure and includes the first outer spacer layer 610, the second outer spacer layer 620 and the third outer spacer layer 630 from inside to outside. That is, the number of layers of the outer spacer 600 is greater than the number of layers of the inner spacer 500. For details of the inner spacer 500 and the outer spacer 600, references may be made to the above description and are not repeated herein.

The semiconductor device 1 may further include two doped regions 710 and 720 disposed in the substrate 100, in which the doped region 710 is disposed adjacent to the first memory gate 201, and the other doped region 720 is disposed adjacent to the second memory gate 202. As mentioned above, the semiconductor device 1 is exemplarily an NMOS transistor. The well region in the substrate 100 is a P-type well region, and the two doped regions 710 and 720 are N-type doped regions. The two doped regions 710 and 720 may be configured as the source line and the bit line of the first memory gate 201 and the second memory gate 202, respectively. In the semiconductor device 1, the first memory gate 201 and the second memory gate 202 share the select gate 400 to form a dual-bit memory cell, which is beneficial to enhancing memory density and reducing volume. The first memory gate 201 and the second memory gate 202, for example, may be erased through Fowler-Nordheim (F-N) tunneling or hot-hole injection, and may be programed by source side injection.

Compared with the prior art, the method for fabricating the semiconductor device of the present disclosure can simultaneously form the first memory gate and the second memory gate at both sides of the select gate, so that the first memory gate and the second memory gate can share the select gate. Compared with the configuration of one memory gate using one select gate, the present disclosure is beneficial to enhancing memory density and reducing volume. In addition, in the method for fabricating the semiconductor device of the present disclosure, the first spacer is used a portion of the etching mask when forming the second recess that defines the select gate, and used as the etching mask when defining the first memory gate and the second memory gate. The remaining portion of the first spacer can be used as a portion of the first memory gate and as a portion of the second memory gate. Therefore, the material forming the semiconductor device can be used as the etching mask during the process, and there is no need to additionally form an etching mask for forming the second recess defining the select gate and additionally form an etching mask for defining the first memory gate and the second memory gate. Accordingly, it is beneficial to simplify the process and reduce the production costs. Given the above, the semiconductor device of the present disclosure can have the advantages of enhanced memory density, reduced volume and lower production cost.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a first memory gate disposed on a substrate;
a second memory gate disposed on the substrate;
a select gate disposed on the substrate and between the first memory gate and the second memory gate; and
an inner spacer disposed on a side surface of the select gate, wherein each of the first memory gate and the second memory gate comprises a capping layer disposed at a top end thereof, each of the capping layers has a curved side surface facing the select gate, and a top end of the inner spacer is adjacent to a bottom end of each of the capping layers.

2. The semiconductor device of claim 1, further comprising:
an outer spacer disposed on an outer side surface of the first memory gate and an outer side surface of the second memory gate, wherein a top end of the outer spacer is aligned with a top surface of each of the capping layers.

3. The semiconductor device of claim 2, wherein each of the inner spacer and the outer spacer is a multi-layer structure, and a number of layers of the outer spacer is greater than a number of layers of the inner spacer.

4. The semiconductor device of claim 1, further comprising:
two doped regions disposed in the substrate, wherein one of the doped regions is adjacent to the first memory gate, and another one of the doped regions is adjacent to the second memory gate.

5. The semiconductor device of claim 1, wherein each of the first memory gate and the second memory gate further comprises a gate insulating layer, a charge storage layer, a blocking insulating layer and a conductive gate layer sequentially disposed on the substrate.

6. The semiconductor device of claim 1, wherein the select gate comprises a gate insulating layer and a conductive gate layer sequentially disposed on the substrate.

7. The semiconductor device of claim 1, wherein each of the capping layers has an asymmetrical cross-sectional shape.

8. The semiconductor device of claim 1, wherein each of the capping layers has a vertical side surface opposite to the curved side surface.

9. The semiconductor device of claim 1, wherein a top surface of the select gate is lower than a top surface of each of the capping layers.

10. The semiconductor device of claim 1, wherein a top surface of the select gate is higher than the top end of the inner spacer.

11. A method for fabricating a semiconductor device, comprising:
sequentially forming a first gate material stack and a hard mask on a substrate;
removing a portion of the hard mask to form a first recess;
forming a first spacer on a side surface of the hard mask facing the first recess;
removing a portion of the first gate material stack not covered by the first spacer and the hard mask to form a second recess;
forming an inner spacer on a side surface of the first gate material stack facing the second recess;
forming a second gate material stack in the first recess and the second recess;
removing a remaining portion of the hard mask; and
removing another portion of the first gate material stack not covered by the first spacer, a portion of the second gate material stack and a portion of the first spacer to form a first memory gate, a second memory gate and a select gate on the substrate, wherein a remaining portion of the first spacer forms a capping layer of the first memory gate and a capping layer of the second memory gate.

12. The method of claim 11, further comprising:
forming an outer spacer on an outer side surface of the first memory gate and an outer side surface of the second memory gate, wherein a top end of the outer spacer is aligned with a top surface of each of the capping layers.

13. The method of claim 12, wherein each of the inner spacer and the outer spacer is a multi-layer structure, and a number of layers of the outer spacer is greater than a number of layers of the inner spacer.

14. The method of claim 11, further comprising:
forming two doped regions in the substrate, wherein one of the doped regions is adjacent to the first memory gate, and another one of the doped regions is adjacent to the second memory gate.

15. The method of claim 11, wherein forming the first gate material stack comprises sequentially forming a gate insulating material layer, a charge storage material layer, a blocking insulating material layer and a conductive gate material layer on the substrate.

16. The method of claim 11, wherein forming the second gate material stack comprises sequentially forming a gate insulating material layer and a conductive gate material layer on the substrate.

17. The method of claim 11, wherein each of the capping layers has a curved side surface facing the select gate.

18. The method of claim 11, wherein the inner spacer is disposed on a side surface of the select gate, and a top end of the inner spacer is adjacent to a bottom end of each of the capping layers.

19. The method of claim 11, wherein removing the portion of the first gate material stack not covered by the first spacer and the hard mask is performed by a self-aligned etch process with the first spacer and the hard mask as an etching mask.

20. The method of claim 11, wherein removing the another portion of the first gate material stack not covered by the first spacer is performed by a self-aligned etch process with the first spacer as an etching mask.
